(19) United States
(12) Patent Application Publication
(10) Pub. No.: US 2008/0048335 A1
(43) Pub. Date: Feb. 28, 2008

(54) SEMICONDUCTOR DEVICE

(76) Inventor: Jae-Won Han, Gyeongi-do (KR)

Correspondence Address: SHERR & NOURSE, PLLC, 620 HERNDON PARKWAY, SUITE 200, HERNDON, VA, 20170, US

(21) Appl. No.: 11/834,389

(22) Filed: Aug. 6, 2007

(30) Foreign Application Priority Data
Aug. 23, 2006 (KR) 10-2006-0080122

(51) Int. Cl. H01L 23/52; H01L 21/00; H01L 23/48

(52) U.S. Cl. 257/774; 257/777; 438/109; 257/E23.01; 257/E23.141; 257/E21.001

(57) ABSTRACT

A semiconductor device according to embodiments may include an interposer, a plurality of devices stacked and formed on the interposer, through electrodes each formed in the plurality of devices and formed by penetrating through the respective devices, and connecting electrodes formed between the respective devices and connecting a through electrode formed in a upper device to a through electrode formed in a lower device.

The present application claims priority under 35 U.S.C. 119 and 35 U.S.C. 365 to Korean Patent Application No. 10-2006-0080122 (filed on Aug. 23, 2006), which is hereby incorporated by reference in its entirety.

### BACKGROUND

FIG. 1 is a drawing illustrating a semiconductor device in a System In a Package (SiP) shape fabricated according to a related art method of fabricating a semiconductor device.

The semiconductor device in a SiP shape according to the related art may include interposer 11, first device 13, second device 15, and third device 17, as shown in FIG. 1.

First to third devices 13, 15, and 17 may be, for example, a CPU, SPRM, DRAM, Flash Memory, Logic LSI, Power IC, Control IC, Analog LSI, MM IC, CMOS RF-IC, Sensor Chip, and MEMS Chip, etc.

Between first device 13 and second device 15, and between second device 15 and third device 17 a connector for connecting signals between the respective devices may be formed, respectively.

To implement commercialization of the semiconductor device having a SiP shape having such a structure, a problem may arise regarding heat radiation. In particular, the problem of heat emission of a device formed in an interlayer such as second device 15 may inhibit the commercialization thereof of the semiconductor device.

### SUMMARY

Embodiments relate to a semiconductor device and a method of fabricating a semiconductor device, which may emit heat from a semiconductor device in a SiP shape in an efficient manner.

According to embodiments, a semiconductor device may include an interposer, a plurality of devices stacked and formed on the interposer, through electrodes each formed in the plurality of devices and formed by penetrating through the respective devices, and connecting electrodes formed between the respective devices and connecting a through electrode formed in a upper device to a through electrode formed in a lower device.

According to embodiments, a method of fabricating a semiconductor device may include forming a plurality of devices having through electrodes penetrating through the devices therein, and stacking and forming the plurality of devices on an interposer.

### DRAWINGS

FIG. 1 is an illustration of a semiconductor device in a System In a Package (SiP) shape fabricated according to a related art method of fabricating a semiconductor device.

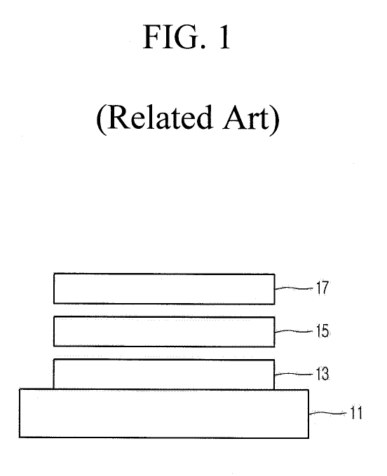

FIG. 2 is an illustration a semiconductor device in a System In a Package (SiP) shape fabricated according to embodiments.

FIG. 3 is an illustration of a semiconductor device in a System In a Package (SiP) shape fabricated according to embodiments.

FIG. 4 is an illustration of a semiconductor device in a System In a Package (SiP) shape fabricated according to embodiments.

### DETAILED DESCRIPTION

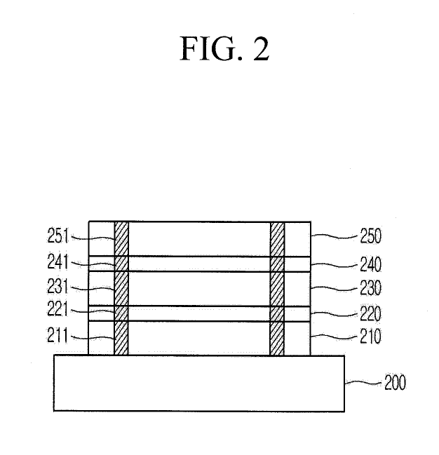

FIG. 2 is an illustration of a semiconductor device in a System In a Package (SiP) shape fabricated according to embodiments.

The semiconductor device according to embodiments may include interposer 200, first device 210, second device 230, and third device 250, as shown in FIG. 2. The semiconductor device may include first through electrode 211 that may penetrate through first device 210. The semiconductor device may include second through electrode 231 that may penetrate through second device 230 and third through electrode 251 that may penetrate through third device 250.

The semiconductor device according to embodiments may include first connecting layer 220 that may connect first device 210 to second device 230. The semiconductor device may include second connecting layer 240 connecting second device 230 to third device 250. First connecting electrode 221 may be formed on first connecting layer 220 and second connecting electrode 241 may be formed on second connecting layer 240. First device 210 may be electrically connected to second device 230 using first connecting electrode 221. Second device 230 may be electrically connected to third device 250 using second connecting electrode 241. First connecting electrode 221 may connect first through electrode 211 to second through electrode 231. Second connecting electrode 241 may connect second through electrode 231 to third through electrode 251.

In embodiments of the semiconductor device in a SiP shape having such a stacked structure, both a device formed on the uppermost portion and a device formed on the lowermost portion may be electrically connected. Through such a connection structure the respective devices may emit heat externally. In embodiments, the respective devices may efficiently emit heat generated from a device formed in an interlayer.

In embodiments, semiconductor devices may be provided with ground electrodes. Therefore, the ground electrodes formed on first to third devices 210, 230, and 250 may be electrically connected so that heat generated from respective devices may be more efficiently emitted. In embodiments, respective ground electrodes may be applied with the same voltage so that there may not be any problem in the flow or the operation of electrical signals. First through electrode 211 may be formed to be connected to the ground electrode provided in first device 210. Second through electrode 231 may be formed to be connected to the ground electrode provided in second device 230. Third through electrode 251 may be formed to be connected to the ground electrode provided in third device 250.

In embodiments, first through electrode 211 may not be formed in first device 210. However, first through electrode 211 may be formed as one scheme for more efficiently emitting heat generated from the respective devices.

In embodiments, through electrode may be formed by sequentially progressing a pattern process, an etching process, a formation process of metal, and CMP process for the semiconductor substrate. Such processes are known and may be not the main concerns in embodiments. Hence a description thereof will be omitted herein.

According to embodiments, the through electrode may be formed of at least one of W, Cu, Al, Ag, and Au, etc. The through electrode may be deposited by CVD, PVD, Evaporation, and ECP, etc. A barrier metal of the through electrode may be any of TaN, Ta, TiN, Ti, and TiSIN, etc., and may be formed by CVD, PVD, and ALD, etc.

In embodiments, a semiconductor device in a SiP shape wherein first to third devices 210, 230, and 250 may be stacked and formed as described, a number of devices that may be stacked can be variously modified. The respective devices may be, for example, any one of CPU, SRAM, DRAM, Flash Memory, Logic LSI, Power IC, Control IC, Analog LSI, MM IC, CMOS RF-IC, Sensor Chip, and MEMS Chip, etc.

In embodiments, a method of fabricating a semiconductor device may include forming a plurality of devices having through electrodes penetrating through the devices therein, and stacking and forming the plurality of devices on an interposer. According to embodiments, stacking and forming the plurality of devices on an interposer may include forming a connecting layer between the respective devices and connecting the through electrodes formed on the upper device and the lower device through the connecting electrode formed on the connecting layer.

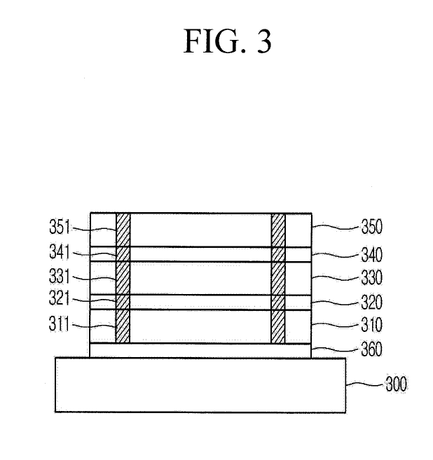

Referring to FIG. 3, in embodiments, a semiconductor in a SiP shape device may be fabricated as a scheme for more efficiently emitting the heat generated from the respective devices.

The semiconductor device according to embodiments may include interposer 300, first device 310, second device 330, and third device 350, as shown in FIG. 3. The semiconductor device may include first through electrode 311 that may penetrate through first device 310. The semiconductor device may include second through electrode 331 that may penetrate through second device 330 and third through electrode 351 that may penetrate through third device 350.

The semiconductor device according to embodiments may include first connecting layer 320 that may connect first device 310 to second device 330. The semiconductor device may include second connecting layer 340 that may connect second device 330 to third device 350. First connecting electrode 321 may be formed on first connecting layer 320. Second connecting electrode 341 may be formed on second connecting layer 340. First device 310 may be electrically connected to second device 330 by first connecting electrode 321. Second device 330 may be electrically connected to third device 350 by second connecting electrode 341. The first connecting electrode 321 may connect first through electrode 311 to second through electrode 331. Second connecting electrode 241 may connect second through electrode 231 to third through electrode 251.

In embodiments, a semiconductor device in a SiP shape having such a stacked structure, both a device formed on an uppermost portion and a device formed on a lowermost portion may be electrically connected. Through such a connection structure the respective devices may emit heat externally (i.e. outside of the device). In embodiments, respective devices may efficiently emit heat generated from a device formed in an interlayer.

In embodiments, whole semiconductor devices may be provided with ground electrodes. The ground electrodes formed on the first to third devices 310, 330, and 350 may be electrically connected so that heat generated from the respective devices can efficiently be emitted. In embodiments, the respective ground electrodes may be applied with the same voltage which may reduce problem in the flow or the operation of electrical signals. First through electrode 311 may be formed to be connected to the ground electrode provided in first device 310. Second through electrode 331 may be formed to be connected to the ground electrode provided in second device 330. Third through electrode 351 may be formed to be connected to the ground electrode provided in third device 350.

In embodiments, separate metal film 360 may be formed on a lower surface of first device 310. Metal film 360 may be formed on a lower surface of first device 310 by any method, such as CVD, PVD, Evaporation, ECP, etc. In embodiments, metal film 360 may be connected to the respective devices through the through electrodes and heat generated from the respective devices may be more efficiently be emitted.

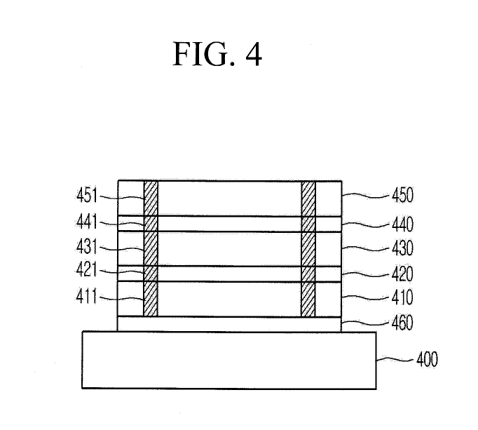

Referring to FIG. 4, in embodiments, a semiconductor in a SiP shape device may be fabricated as a scheme for more efficiently emitting the heat generated from the respective devices.

The semiconductor device according to embodiments may include an interposer 400, first device 410, second device 430, and third device 450, as shown in FIG. 4. The semiconductor device may include a first through electrode 411 penetrating through first device 410. The semiconductor device may include a second through electrode 431 penetrating through second device 430 and a third through electrode 451 penetrating through third device 450.

The semiconductor device according to embodiments may include a first connecting layer 420 connecting first device 410 to second device 430. The semiconductor device may include second connecting layer 440 connecting second device 430 to third device 450. First connecting electrode 421 may be formed on first connecting layer 420. Second connecting electrode 441 may be formed on second connecting layer 440. First device 410 may be electrically connected to second device 430 by first connecting electrode 421. Second device 430 may be electrically connected to third device 450 by second connecting electrode 441. First connecting electrode 421 may connect first through electrode 411 to second through electrode 431. Second connecting electrode 441 may connect second through electrode 431 to third through electrode 451.

According to embodiments, in a semiconductor device in a SiP shape having such a stacked structure, both a device formed on an uppermost portion and a device formed on a lowermost portion can be electrically connected. Through such a connection structure the respective devices may emit heat externally from the device. In embodiments, the respective devices may efficiently emit the heat generated from a device formed in an interlayer.

According to embodiments, the whole semiconductor device may be provided with ground electrodes. Ground electrodes formed on first to third devices 410, 430, and 450 may be electrically connected and the heat generated from the respective devices may be efficiently emitted. Also, the respective ground electrodes may be applied with the same voltage, which may reduce or eliminate a problem in the flow or the operation of electrical signals.

First through electrode 411 may be formed to be connected to a ground electrode provided in first device 410. Second through electrode 431 may be formed to be connected to the ground electrode provided in second device 430. Third through electrode 451 may be formed to be connected to the ground electrode provided in third device 450.

According to embodiments, separate heat radiation device 460 may be formed on a lower surface of first device 410. In embodiments, heat radiation device 460 may be connected to the respective devices through the through electrode and the heat generated from the respective devices may be more efficiently be emitted. In embodiments, heat radiation device 460 may be a heat sink or a heat pipe.

According to embodiments, heat emission may be performed more smoothly and efficiently by providing a pipe capable of injecting cooling substance between the first device and the interposer and then contacting them.

With the semiconductor device and the fabricating method thereof according to embodiments, there may be an advantage that heat can easily be emitted from the semiconductor device in a SiP shape.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device comprising:
an interposer;
a plurality of devices stacked over the interposer;
a through electrode formed in each of the plurality of devices and configured to penetrate through the respective device; and
connecting electrodes formed between the respective devices and configured to connect the through electrode formed in an upper device to the through electrode formed in a lower device.

2. The device of claim 1, wherein the through electrodes formed in each of the plurality of devices are connected to ground electrodes of the respective devices.

3. The device of claim 1, further comprising a metal film formed between the interposer and the stacked plurality of devices and coupled to the through electrode formed in the lower device.

4. The device of claim 1, further comprising a heat radiator formed between the interposer and the stacked plurality of devices and coupled to the through electrode formed in the lower device.

5. The device of claim 4, wherein the heat radiator comprises at least one of a heat sink and a pipe.

6. The device of claim 1, wherein the through electrode comprises at least one of W, Cu, Al, Ag, and Au.

7. The device of claim 1, wherein each of the plurality of devices comprises one of a CPU, SPRM, DRAM, Flash Memory, Logic LSI, Power IC, Control IC, Analog LSI, MM IC, CMOS RF-IC, Sensor Chip, and MEMS Chip.

8. A method, comprising:
forming a plurality of devices, each one having through electrodes penetrating through the respective devices; and
stacking the plurality of devices over an interposer, wherein through electrodes of adjacently stacked devices are coupled together.

9. The method of claim 8, wherein stacking the plurality of devices over the interposer comprises forming a connecting layer between the respective devices and connecting the through electrodes formed on an upper device and a lower device through the connecting electrode formed within the connecting layer.

10. The method of claim 8, wherein the through electrodes formed in the respective devices are connected to ground electrodes of the respective devices.

11. The method of claim 8, further comprising forming a metal film between the interposer and the plurality of stacked devices.

12. The method of claim 8, further comprising forming a heat radiator between the interposer and the plurality of stacked devices.

13. The method of claim 12, wherein the heat radiator comprises a heat sink.

14. The method of claim 12, wherein the heat radiator comprises a pipe.

15. The method of claim 14, further comprising injecting a cooling substance into the pipe.

16. The method of claim 8, wherein the through electrodes comprise at least one of W, Cu, Al, Ag, and Au.

17. The method of claim 8, wherein each of the plurality of devices comprises at least one of a CPU, SPRM, DRAM, Flash Memory, Logic LSI, Power IC, Control IC, Analog LSI, MM IC, CMOS RF-IC, Sensor Chip, and MEMS Chip.

18. A device, comprising:
an interposer layer;
a heat dispersing layer formed over the interposer layer;
a first device formed over the heat dispersing layer and having a first through electrode formed therein passing through the first device from a first device top surface to a first device bottom surface;
a second device formed over the first device and having a second through electrode formed therein passing through the second device from a second device top surface to a second device bottom surface; and
a connecting electrode formed between the first device and second device, and coupled to the first and second through electrodes.

19. The device of claim 18, wherein the heat dispersing layer comprises one of a metal layer, a heat sink, and a pipe.

20. The device of claim 19, wherein the first through electrode is connected to a ground electrode of the first device, and the second through electrode is connected to a ground electrode of the second device.
